(19) United States
(12) Patent Application Publication
(10) Pub. No.: US 2019/0123712 A1
(43) Pub. Date: Apr. 25, 2019

(54) TUNING-FORK CRYSTAL UNIT AND PACKAGE

(71) Applicant: NIHON DEMPA KOGYO CO., LTD., Tokyo (JP)

(72) Inventors: Yoshikazu HASUIKE, Saitama (JP); Shingo KAWANISHI, Saitama (JP)

(73) Assignee: NIHON DEMPA KOGYO CO., LTD., Tokyo (JP)

(21) Appl. No.: 16/163,575

(22) Filed: Oct. 18, 2018

(30) Foreign Application Priority Data
Oct. 20, 2017 (JP) 2017-203678

(51) Int. Cl. H03H 9/10; H03H 9/21

(52) U.S. Cl. CPC H03H 9/10; H03H 9/21

(57) ABSTRACT

There is provided a tuning-fork crystal unit that includes a tuning-fork piece, excitation electrodes, a package, wiring patterns and frequency adjustment portions. The tuning-fork piece has a base portion and at least two vibration arms. The at least two vibration arms extend from the base portion. The excitation electrodes are disposed at the tuning-fork piece. The package houses the tuning-fork piece. The wiring patterns are disposed at a surface of the package which houses the tuning-fork piece. The wiring patterns are a part of wirings connecting the excitation electrodes to outside. The frequency adjustment portions are disposed at distal ends of the vibration aims. The wiring patterns have parts positioned near the frequency adjustment portions. The parts are disposed at regions of the package hidden by the frequency adjustment portions.

### CROSS-REFERENCE TO RELATED APPLICATIONS

This application is based on and claims priority under 35 U.S.C. § 119 to Japanese Patent Application No. 2017-203678, filed on Oct. 20, 2017, the entire content of which is incorporated herein by reference.

### TECHNICAL FIELD

This disclosure relates to a tuning-fork crystal unit that has a feature in an arrangement of wiring patterns in a package and the package.

### DESCRIPTION OF THE RELATED ART

As one kind of a tuning-fork crystal unit, there has been provided a tuning-fork type crystal unit, and further as one kind of the tuning-fork type crystal unit, there has been provided one using a ceramic package. For example, Japanese Unexamined Patent Application Publication No. 2017-76910 discloses one example of the tuning-fork type crystal unit in FIG. 3. In this example, a ceramic package has depressed portions that house tuning-fork type crystal elements. These depressed portions include electrode pads and wiring patterns at a bottom surface. Penetration wirings are disposed at a bottom plate of this ceramic package, and external connecting terminals are disposed on an outer bottom surface.

The electrode pads in the depressed portions and excitation electrodes of the tuning-fork type crystal elements are connected with conductive adhesives. The external connecting terminals and the excitation electrodes are connected via the penetration wirings, the wiring patterns, the electrode pads, and the conductive adhesives.

When a tuning-fork type crystal unit is manufactured, a frequency is adjusted such that this crystal unit vibrates at a predetermined frequency. The typical method includes a method that preliminarily includes weight films made of metal such as gold at distal ends of two vibration arms of tuning-fork and irradiates these weight films with ion made of, for example, argon to remove a part of the weight films, thus matching the frequency to an aimed frequency. The method is a so-called ion milling method.

However, in association with downsizing of the tuning-fork type crystal unit, a distance between the above-described wiring patterns, which are formed at the ceramic package, has also been narrowing more and more. Similarly, between a part of the penetration wiring exposed to the package surface, which is a part of the wiring pattern, and the wiring pattern with an opposite polarity has also been narrowing more and more. In a package of a mold sealed using a technique such as a seam ring welding and a gold tin welding as one kind of a ceramic package, a seam ring and a gold tin ring are disposed on a top surface of a dike around the above-described depressed portions housing the crystal elements. In such situation, there may be a case where the weight films for frequency adjustment removed at the above-described ion milling and further a metallic composition of the wiring patterns at the bottom surface of the package attaches again to a part between the wiring patterns at the bottom surface of the package. Similarly, the above-described metallic composition possibly attaches again to a part between the wiring patterns at the bottom surface of the package, and the seam ring and the gold tin ring. Such re-attachment deteriorates an insulation resistance of the tuning-fork type crystal unit, possibly degrading reliability of the tuning-fork type crystal unit.

A need thus exists for a tuning-fork crystal unit and a package which are not susceptible to the drawback mentioned above.

### SUMMARY

According to an aspect of this disclosure, there is provided a tuning-fork crystal unit that includes a tuning-fork piece, excitation electrodes, a package, wiring patterns and frequency adjustment portions. The tuning-fork piece has a base portion and at least two vibration arms. The at least two vibration arms extend from the base portion. The excitation electrodes are disposed at the tuning-fork piece. The package houses the tuning-fork piece. The wiring patterns are disposed at a surface of the package which houses the tuning-fork piece. The wiring patterns are a part of wirings connecting the excitation electrodes to an outside. The frequency adjustment portions are disposed at distal ends of the vibration arms. The wiring patterns have parts positioned near the frequency adjustment portions. The parts are disposed at regions of the package hidden by the frequency adjustment portions.

### BRIEF DESCRIPTION OF THE DRAWINGS

The foregoing and additional features and characteristics of this disclosure will become more apparent from the following detailed description considered with reference to the accompanying drawings, wherein:

FIGS. 1A, 1B, and 1C are drawings describing a tuning-fork type crystal unit 10 of a first embodiment;

FIGS. 2A and 2B are drawings especially describing an excitation electrode of a tuning-fork type crystal unit;

FIG. 3A is a drawing describing a main part of a tuning-fork type crystal unit of a working example, and FIG. 3B is a drawing describing a main part of a tuning-fork type crystal unit of a comparative example; and

FIGS. 4A and 4B are drawings describing a tuning-fork type crystal unit 40 of a second embodiment.

### DETAILED DESCRIPTION

The following describes respective embodiments of the disclosure of a tuning-fork type crystal unit and a package of this application with reference to the drawings. Each drawing used in the description is merely illustrated schematically for understanding the embodiments. In each drawing used in the descriptions, like reference numerals designate corresponding or identical elements, and therefore such elements will not be further elaborated here. Shapes, dimensions, material, and similar factor described in the following description are merely preferable examples within the scope of the embodiments. Therefore, the disclosure of this application is not limited to only the following embodiments.

1. Tuning-Fork Type Crystal Unit and Package of First Embodiment

1-1. Description of Structure

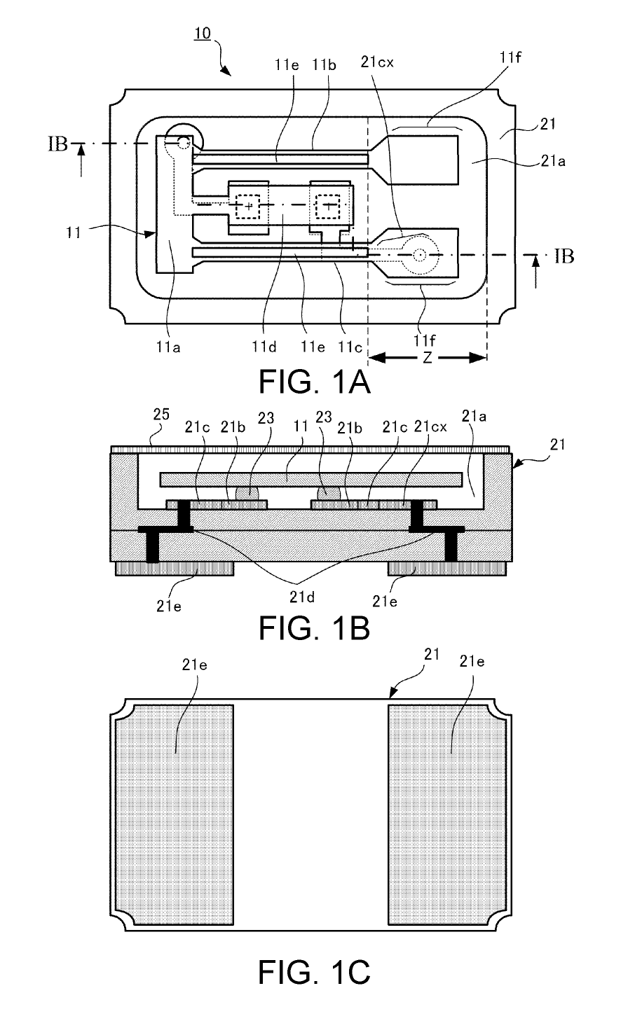

FIGS. 1 A to 1C are drawings describing a tuning-fork type crystal unit 10 of the first embodiment. Especially, FIG. 1A illustrates a plan view, FIG. 1B illustrates a cross-sectional view taken along a line IB-IB in FIG. 1A, and FIG. 1C is a bottom view.

This tuning-fork type crystal unit 10 includes a tuning-fork type crystal element 11 and a package 21 that houses the tuning-fork type crystal element 11. A planar outer size of the tuning-fork type crystal unit 10 that significantly exhibits effects of the disclosure is a crystal unit with a long side dimension of 1.6 mm or less and a short side dimension of 1.0 mm or less, so-called 1610 size and 1210 size or less. Obviously, this disclosure may be applied to a tuning-fork type crystal unit with a size larger than these sizes.

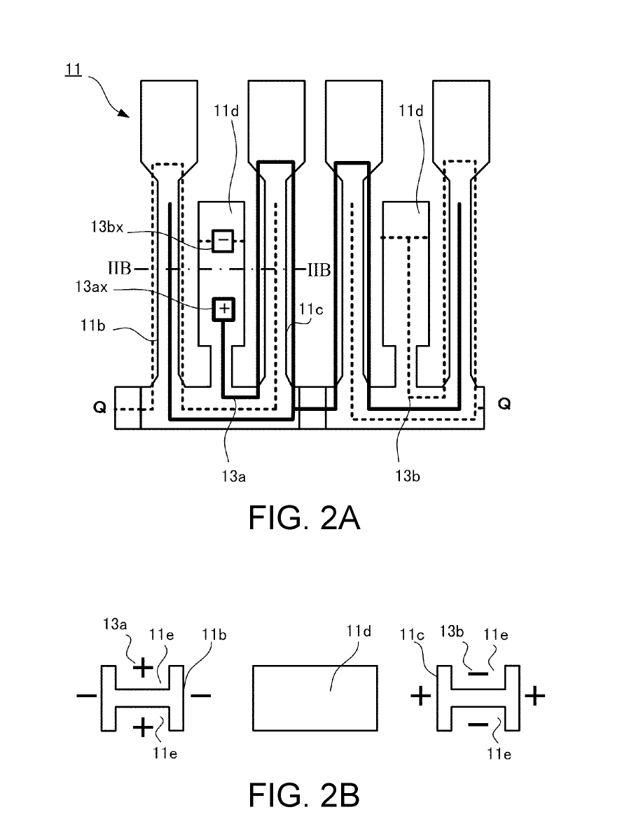

The tuning-fork type crystal element 11 includes a base portion 11a, a first vibration arm 11b and a second vibration arm 11c, a supporting arm 11d, grooves 11e, frequency adjustment portions 11f, a first excitation electrode 13a, and a second excitation electrode 13b (see FIGS. 2A and 2B).

The first vibration arm 11b and the second vibration arm 11c extend parallel to one another from the base portion 11a. The respective first vibration arm 11b and second vibration arm 11c in this case have widths of distal end portions wider than those of other parts. This wide width parts serve as the frequency adjustment portions 11f That is, metal films such as gold are formed as weight films at these wide width parts, and a frequency is adjusted by removing these weight films by an ion milling method.

The grooves 11e are disposed on both front and back surfaces of the respective first vibration arm 11b and second vibration arm 11c at a predetermined depth. Although the details are omitted, these grooves 11e are to efficiently apply an electric field of a drive signal to the tuning-fork type crystal unit. FIG. 2A described later omits the illustration of the grooves 11e.

The supporting arm 11d extends between the first vibration arm 11b and the second vibration arm 11c from the base portion 11 a parallel to these vibration arms. This crystal element 11 can be formed by a well-known photolithography technology.

In such crystal element 11, excitation electrodes are disposed on eight surfaces in total of the first vibration arm 11b and the second vibration arm 11c. The following describes this configuration with reference to FIGS. 2A and 2B. Here, FIG. 2A is equivalent to a drawing of developing the crystal element 11. That is, FIG. 2A is a development diagram with a gist of forming a tuning-fork shape by folding the development diagram of FIG. 2A in the lateral direction of the paper surface and connecting two portions indicated by Q together. FIG. 2B is a cross-sectional view taken along a line IIB-IIB in FIG. 2A.

In FIG. 2A, a solid line for which 13a is assigned is a first excitation electrode and a dashed line for which 13b is assigned is a second excitation electrode. FIG. 2B illustrates that these excitation electrodes 13a and 13b are also disposed in and at side surfaces of the grooves 11e of the vibration arms. The “+” indications in FIG. 2B indicate, for example, the first excitation electrodes and the “−” indications indicate the second excitation electrodes. Like the example of FIG. 2B, when an electric field is applied to the vibration arms with the polarities indicated by “+” and “−” at a certain time and the electric field is applied to the vibration arms with polarities opposite to the case of FIG. 2B at the subsequent time, a flexure vibration occurs.

The respective first excitation electrode 13a and second excitation electrode 13b serve as terminating ends at the supporting arms 11d as pads 13ax and 13bx for connection with the package 21.

Meanwhile, the package 21 includes a depressed portion 21a, connection pads 21b, wiring patterns 21c, penetration wirings 21d, and external connecting terminals 21e. This package 21 is typically can be configured by a ceramic package. The following describes the respective portions/units.

The depressed portion 21a has a depth and a planar shape by which the crystal element 11 can be housed. The connection pads 21b are disposed on a bottom surface of the depressed portion 21a and at positions corresponding to the above-described pads 13ax and 13bx.

The wiring patterns 21c are disposed on the bottom surface of the depressed portion 21a. This disclosure features the arrangement of the wiring patterns 21c, and this first embodiment employs an arrangement as follows. That is, as illustrated in the plan view of FIG. 1A, a part 21cx, which is positioned near the frequency adjustment portion 11f, of the wiring pattern 21c, is disposed at the bottom surface of the depressed portion 21a and a region hidden by the frequency adjustment portion 11f. That is, this part 21cx is disposed at the bottom surface of the depressed portion 21a and the region corresponding to below the frequency adjustment portion 11f. Here, the part 21cx, which is positioned near the frequency adjustment portion 11f, of the wiring pattern 21c indicates a region possibly causing a poor insulation between wirings by a deposition of a metallic composition removed when the weight film of the frequency adjustment portion 11f is removed by the ion milling on the bottom surface of the depressed portion 21a of the package 21. Although not limited to this, for example, the region is a region (the region indicated by Z in FIG. 1A) from a distal end side of the grooves 11e disposed on the vibration arms to a wall of the package on a distal end side of the tuning-fork in the bottom surface of the depressed portion 21a of the package 21.

The penetration wirings 21d are disposed on the bottom plate of the package. When the connection positions of these penetration wirings 21d with the wiring patterns 21c are disposed near the frequency adjustment portions 11f, the connection positions are at the regions hidden by the frequency adjustment portions 11f similar to the above-described arrangement of the wiring patterns. This embodiment employs a structure that constitutes the bottom plate of the package 21 by two sheets and the penetration wirings 21d reach the external connecting terminals 21e via holes disposed at different positions on the two bottom plates. Although the one bottom plate is used and the penetration wirings may be disposed at the bottom plate, the configuration that provides the penetration wirings via the holes disposed at the different positions on the two bottom plates facilitates securing air tightness of the package.

Additionally, the external connecting terminals 21e are terminals disposed on the outer bottom surface of the package 21 and that connect the tuning-fork type crystal unit 10 to external electronic equipment or similar equipment.

The above-described crystal element 11 and package 21 are connected with preferable connecting members, for example, conductive adhesives 23 (see FIG. 1B) at positions of the pads 13ax and 13bx of the excitation electrodes with the connection pads 21b on the package side.

A lid member 25 is joined to a top surface of a dike portion around the depressed portion 21a of the package 21, thus sealing the crystal element 11 in the package 21. As a sealing method, any method according to the design of the tuning-fork type crystal unit is usable. For example, a seam welding and a vacuum sealing method are usable.

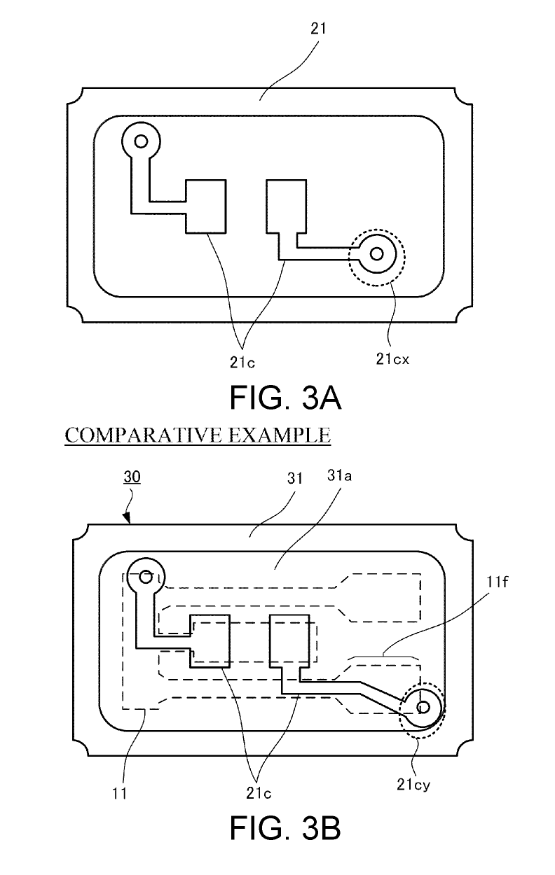

FIG. 3A is a plan view illustrating a state of removing the tuning-fork type crystal element 11 from the tuning-fork type crystal unit 10 illustrated in the plan view of FIG. 1A to especially clarify the arranged positions of the wiring patterns of the package used in the first embodiment. FIG. 3B is a plan view illustrated similar to FIG. 1A to describe a tuning-fork type crystal unit 30 and a package 31 of a comparative example. With the tuning-fork type crystal unit 30 of the comparative example, a one part 21cy of the wiring pattern 21c is positioned at a part not hidden by the frequency adjustment portion 11f of the crystal element 11 but is exposed when viewed from the above. Moreover, the one part 21cy of the wiring pattern is arranged up to an edge of a dike of a depressed portion 31a of the package 31.

1-2. Description of Effects of First Embodiment

The tuning-fork type crystal unit 10 of the first embodiment, which has been described using FIGS. 1A to 1C, FIGS. 2A and 2B, and FIG. 3A, and the tuning-fork type crystal unit 30 of the comparative example, which has been described using FIG. 3B, were manufactured. Additionally, after removal of a predetermined amount of the weight films at the frequency adjustment portions by an ion milling method, the tuning-fork type crystal unit 10 and the tuning-fork type crystal unit 30 were sealed. An insulation resistance inspection was conducted on 1,000 pieces of each of the tuning-fork type crystal units 10 and 30. Then, while a poor insulation resistance of the tuning-fork type crystal unit 10 of the first embodiment was zero, the poor insulation of the tuning-fork type crystal unit 30 of the comparative example was 0.5%.

Since this disclosure has the structure of no wiring patterns, the wiring patterns 21c, near the frequency adjustment portions, it can be understood that the poor insulation between the wiring patterns does not occur even when the metallic composition removed from the frequency adjustment portions 11f by the ion milling attaches again to the bottom surface of the depressed portion 21a of the package 21.

2. Second Embodiment

As illustrated in FIG. 1C, while the first embodiment includes the part 21cx of the wiring pattern 21c near the frequency adjustment portion 11f of the crystal element at the position below the frequency adjustment portion 11f and hidden by the frequency adjustment portion 11f, the wiring pattern itself is not reached up to the frequency adjustment portion but may be disposed at the region on the side of the base portion with respect to the frequency adjustment portion. This second embodiment is an example of such configuration.

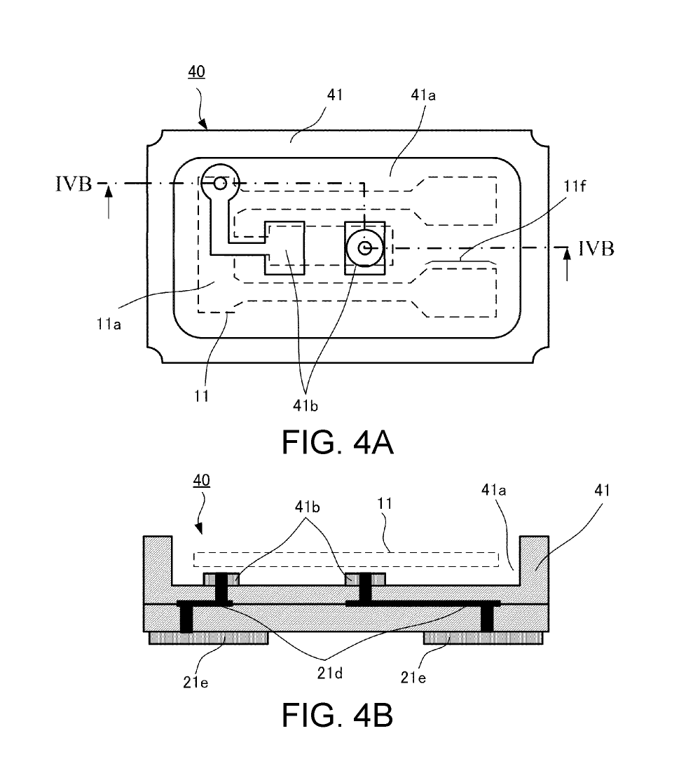

FIGS. 4A and 4B describe a tuning-fork type crystal unit 40 of the second embodiment. Especially, FIG. 4A is a plan view illustrating a tuning-fork type crystal unit 40 of the second embodiment, and FIG. 4B is a cross-sectional view taken along a line IVB-IVB of FIG. 4A. To clarify the positional relationship between a depressed portion 41a and the crystal element 11, these drawings indicate the crystal element 11 by dashed lines.

With the tuning-fork type crystal unit 40 of this second embodiment, wiring patterns 41b themselves are not reached up to the regions of the frequency adjustment portions 11f of the crystal element 11 but disposed at regions on the side of the base portion 11a with respect to the frequency adjustment portions 11f. Since this second embodiment has a structure of no wiring patterns at a bottom surface of the depressed portion 41a and at regions corresponding to at least from the frequency adjustment portions to corners of a package, a poor insulation resistance can be prevented.

While the respective embodiments of the disclosure of this application have been described above, these disclosures are not limited to the above-described examples. For example, the tuning-fork type crystal element is not limited to the above-described three-leg tuning-fork, but this disclosure is applicable to various kinds of tuning-forks such as the usual two-leg tuning-fork and a tuning-fork with two supporting aims, which has one supporting aim at each of both sides of the two-leg tuning-fork. Moreover, the tuning-fork needs not to have a wide-width distal end portion. While the above-described embodiments describe the example of using the tuning-fork type crystal element as a tuning-fork piece, the tuning-fork piece is not limited to the crystal but may be made of another material. Further, while the above-described embodiments describe the examples of the package having the depressed portion as the package, this disclosure is also applicable to a package that includes a flat plate base and a cap having a depressed portion. The planar shape and the position of the wiring pattern are changeable within the scope of the object and the effects of this disclosure.

A tuning-fork crystal unit may include a tuning-fork piece, excitation electrodes, a package, wiring patterns, and frequency adjustment portions. The tuning-fork piece has a base portion and at least two vibration arms. The at least two vibration arms extend from the base portion. The excitation electrodes are disposed at the tuning-fork piece. The package houses the tuning-fork piece. The wiring patterns are disposed at a surface of the package which houses the tuning-fork piece. The wiring patterns are a part of wirings connecting the excitation electrodes to outside. The frequency adjustment portions are disposed at distal ends of the vibration aims. The wiring patterns have parts positioned near the frequency adjustment portions. The parts are disposed at regions of the package hidden by the frequency adjustment portions. That is, these parts may be disposed at the regions of the package corresponding to below the frequency adjustment portions.

Alternatively, the wiring patterns are disposed at regions on a side of the base portion of the package with respect to the frequency adjustment portions.

Alternatively, the wiring patterns are disposed at regions on a side of the base portion of the package with respect to the frequency adjustment portions and regions at least partially hidden by the tuning-fork piece, that is, regions below the tuning-fork piece.

A package according to an aspect of this application houses a tuning-fork piece having a base portion, at least two vibration arms, and frequency adjustment portions at distal ends of the vibration aims. The at least two vibration arms extend from the base portion. The package includes wiring patterns at a surface of the package which houses the tuning-fork piece. The wiring patterns have parts positioned near the frequency adjustment portions. The parts are disposed at regions of the package hidden by the frequency adjustment portions. Alternatively, the wiring patterns are disposed at regions on a side of the base portion of the package with respect to the frequency adjustment portions.

According to the tuning-fork crystal unit and the package of these embodiments, the structure in which the wiring patterns are not exposed near the frequency adjustment portions of the package in plan view is obtained. Therefore, even when the metallic composition of the frequency adjustment portion reaches the region of the package near the frequency adjustment portion by the ion milling, the situation where the metallic composition deposits between the excitation electrodes does not occur. This ensures preventing the insulation resistance between the excitation electrodes from degrading. While the preferable configuration applying the embodiments is the frequency adjustment by the ion milling method, the embodiments are also applicable to the case where the frequency is adjusted by adding the metallic composition to the frequency adjustment portions.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention.

Accordingly, it is expressly intended that all such variations, changes and equivalents which fall within the spirit and scope of the present invention as defined in the claims, be embraced thereby.

What is claimed is:

1. A tuning-fork crystal unit, comprising:
a tuning-fork piece, having a base portion and at least two vibration arms, and the at least two vibration arms extending from the base portion;
excitation electrodes, being disposed at the tuning-fork piece;
a package that houses the tuning-fork piece;
wiring patterns, being disposed at a surface of the package which houses the tuning-fork piece, and the wiring patterns being a part of wirings connecting the excitation electrodes to an outside; and
frequency adjustment portions, being disposed at distal ends of the vibration aims,
wherein the wiring patterns have parts positioned near the frequency adjustment portions, the parts being disposed at regions of the package hidden by the frequency adjustment portions.

2. A tuning-fork crystal unit, comprising:
a tuning-fork piece, having a base portion and at least two vibration arms, and the at least two vibration arms extending from the base portion;
excitation electrodes, being disposed at the tuning-fork piece;
a package that houses the tuning-fork piece;
wiring patterns, being disposed at a surface of the package which houses the tuning-fork piece, and the wiring patterns being a part of wirings connecting the excitation electrodes to an outside; and
frequency adjustment portions, being disposed at distal ends of the vibration arms,
wherein the wiring patterns are disposed at regions on a side of the base portion of the package with respect to the frequency adjustment portions.

3. A package that houses a tuning-fork piece having a base portion, at least two vibration aims, and frequency adjustment portions at distal ends of the vibration arms, the at least two vibration arms extending from the base portion, the package comprising:
wiring patterns, being disposed at a surface of the package which houses the tuning-fork piece,
wherein the wiring patterns have parts positioned near the frequency adjustment portions, the parts being disposed at regions of the package hidden by the frequency adjustment portions.

4. A package that houses a tuning-fork piece having a base portion, at least two vibration arms, and frequency adjustment portions at distal ends of the vibration aims, the at least two vibration arms extending from the base portion, the package comprising:
wiring patterns, being disposed at a surface of the package which houses the tuning-fork piece,
wherein the wiring patterns are disposed at regions on a side of the base portion of the package with respect to the frequency adjustment portions.
